(19) United States
(12) Patent Application Publication
(10) Pub. No.: US 2021/0119160 A1
(43) Pub. Date: Apr. 22, 2021

(54) LIGHT-EMITTING ELEMENT AND DISPLAY DEVICE

(71) Applicant: SHARP KABUSHIKI KAISHA, Sakai City, Osaka (JP)

(72) Inventors: TOKIYOSHI UMEDA, Sakai City, Osaka (JP); YUTO TSUKAMOTO, Sakai City, Osaka (JP); MASAYUKI KANEHIRO, Sakai City, Osaka (JP); YOUHEI NAKANISHI, Sakai City, Osaka (JP)

(21) Appl. No.: 17/041,134

(22) PCT Filed: Mar. 28, 2018
(86) PCT No.: PCT/JP2018/013032

§ 371 Date: Sep. 24, 2020

(51) Int. Cl. H01L 51/50; H01L 27/32

(52) U.S. Cl. CPC H01L 51/502; H01L 51/5056; H01L 27/32; H01L 51/5088; H01L 51/5092; H01L 51/5072

(57) ABSTRACT

A light-emitting element includes a light-emitting layer, a hole transportation layer, and an electron transportation layer. The light-emitting layer includes a quantum dot dopant, and a host formed of a hole transport host and an electron transport host. The quantum dot dopant emits light as a result of exciton energy generated in the host transitioning to the quantum dot dopant.

### TECHNICAL FIELD

The present invention relates to a light-emitting element that uses a quantum dot (QD) dopant.

### BACKGROUND ART

In recent years, a light-emitting element including QD phosphor particles (also referred to as semiconductor nanoparticle phosphors or QD dopants) has been used as a light source of a display device, for example. PTL 1 discloses an example of such a display device. An object of the display device of PTL 1 is to provide a display device with high luminous efficiency and a long life.

### CITATION LIST

### Patent Literature

PTL 1: JP 2014-78381 A

### SUMMARY OF INVENTION

### Technical Problem

However, in the technology disclosed in PTL 1, in a light-emitting layer, electrons or holes supplied from electrodes are not transported sufficiently. Thus, there is a problem in that the balance between the amount of holes and the amount of electrons that are supplied to the QD phosphor particles is reduced, and the luminous efficiency of the light-emitting element including QD phosphor particles is reduced.

An object of an aspect of the present invention is to realize a light-emitting element with high luminous efficiency.

### Solution to Problem

In order to solve the problem described above, a light-emitting element according to an aspect of the present invention includes a light-emitting layer provided between an anode electrode and a cathode electrode, a hole transportation layer provided between the anode electrode and the cathode electrode and configured to transport holes supplied from the anode electrode to the light-emitting layer, and an electron transportation layer provided between the anode electrode and the cathode electrode and configured to transport electrons supplied from the cathode electrode to the light-emitting layer. The light-emitting layer includes a quantum dot dopant, and an exciplex host formed of a hole transport host and an electron transport host, and the quantum dot dopant emits light as a result of exciton energy generated in the exciplex host transitioning to the quantum dot dopant.

### Advantageous Effects of Invention

With the light-emitting device according to an aspect of the present invention, a light-emitting element with high luminous efficiency can be provided.

### BRIEF DESCRIPTION OF DRAWINGS

FIG. 1 is a flowchart illustrating an example of a method for manufacturing a display device according to a first embodiment.

FIG. 2 is a cross-sectional view illustrating a configuration example of a display portion provided in the display device.

FIG. 3 is a schematic diagram illustrating a configuration of a light-emitting element provided in the display portion.

FIG. 4 is a schematic diagram illustrating a configuration of a light-emitting element according to a second embodiment.

### DESCRIPTION OF EMBODIMENTS

### First Embodiment

Hereinafter, a first embodiment of the present invention will be described in detail with reference to the drawings. In the following, a “same layer” refers to a layer formed in the same process using the same material, a “lower layer” refers to a layer formed in a process before a process in which a layer to be compared is formed, and an “upper layer” refers to a layer formed in a process after the process in which the layer to be compared is formed. Further, note that each drawing schematically describes the shape, structure, and positional relationship of each member, and is not necessarily drawn to scale.

In the present embodiment, a display portion 1a of a display device 1 will be described. Descriptions of other members of the display device 1 will be omitted. It may be understood that the members for which descriptions are omitted are similar to those known in the related art. The display device 1 expresses an image using a plurality of red, green and blue (RGB) pixels.

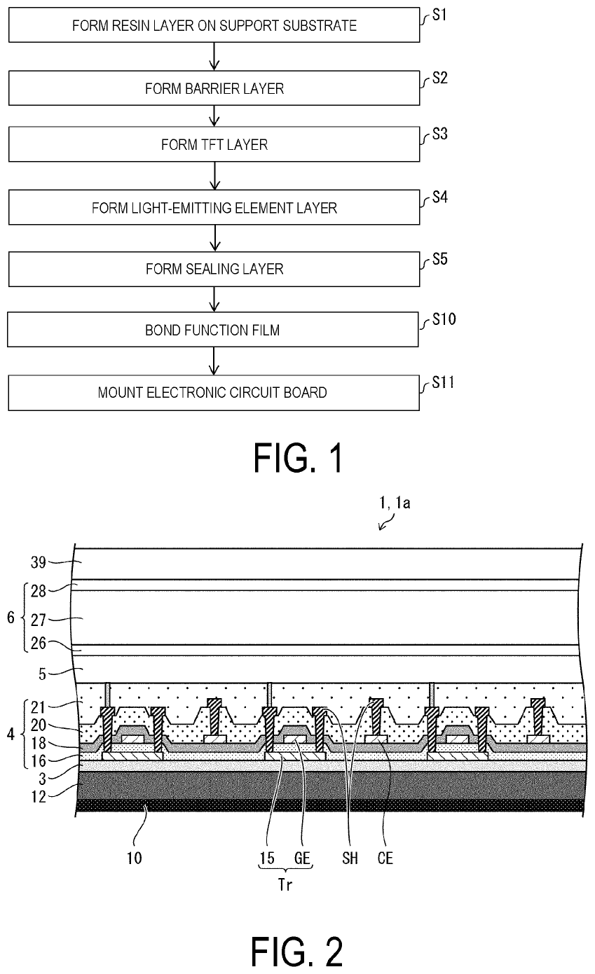

FIG. 1 is a flowchart illustrating an example of a method for manufacturing the display device 1 of the present embodiment. FIG. 2 is a cross-sectional view illustrating a configuration example of the display portion 1a of the display device 1.

As illustrated in FIG. 1 and FIG. 2, when manufacturing the display device 1, first, a resin layer 12 is formed on a transparent support substrate (a mother glass substrate, for example)(not illustrated) (step S1). Next, a barrier layer 3 is formed (step S2). Next, a TFT layer 4 is formed (step S3). Next, a top-emitting type light-emitting element layer 5 is formed (step S4). Step S4 will be described in detail below. Next, a sealing layer 6 is formed (step S5). Next, a function film 39 is bonded to an upper face of the sealing layer 6 (step S6). Next, an electronic circuit board (an IC chip, for example) is mounted on a terminal for external connection, and the display device 1 is configured (step S7). Note that each of the above-described steps is performed by a display device manufacturing apparatus.

Examples of the material of the resin layer 12 include a polyimide resin, an acrylic resin, and an epoxy resin. Examples of the material of the function film 10 include polyethylene terephthalate (PET).

The barrier layer 3 is a layer that inhibits foreign matter, such as water and oxygen, from penetrating the TFT layer 4 and the light-emitting element layer 5 when the display device 1 is used, and can be formed, for example, by a silicon oxide film, a silicon nitride film, or a silicon oxynitride film, or by a layered film of these, formed by chemical vapor deposition (CVD).

The TFT layer 4 includes a semiconductor film 15, an inorganic insulating film 16 (a gate insulating film) as an upper layer overlying the semiconductor film 15, a gate electrode GE as an upper layer overlying the inorganic insulating film 16, an inorganic insulating film 18 as an upper layer overlying the gate electrode GE, a capacitance wiring line CE as an upper layer overlying the inorganic insulating film 18, an inorganic insulating film 20 as an upper layer overlying the capacitance wiring line CE, a source wiring line SH as an upper layer overlying the inorganic insulating film 20, and a flattening film 21 as an upper layer overlying the source wiring line SH.

A thin-film transistor (TFT) Tr is configured to include the semiconductor film 15, the inorganic insulating film 16 (the gate insulating film), and the gate electrode GE.

The semiconductor film 15 is formed of low-temperature polysilicon (UPS) or an oxide semiconductor, for example. Note that, although the TFT including the semiconductor film 15 as a channel is illustrated as having a top gate structure in FIG. 2, the TFT may have a bottom gate structure (when the TFT channel is an oxide semiconductor, for example).

The gate electrode GE, the capacitance electrode CE, and the source wiring line SH are each formed by a single layer film or a layered film of a metal, for example. The metal includes at least one of aluminum (Al), tungsten (W), molybdenum (Mo), tantalum (Ta), chromium (Cr), titanium (Ti), and copper (Cu), for example.

Each of the inorganic insulating films 16, 18, and 20 can be formed of, for example, a silicon oxide (SiOx) film or a silicon nitride (SiNx) film, or a layered film of these, formed using CVD. The flattening film (interlayer insulating film) 21 can be formed of, for example, a coatable photosensitive organic material such as a polyimide or an acrylic.

The sealing layer 6 includes an inorganic sealing film 26 as an upper layer overlying a cathode electrode 51, which will be described below, an organic sealing film 27 as an upper layer overlying the inorganic sealing film 26, and an inorganic sealing film 28 as an upper layer overlying the organic sealing film 27, and inhibits foreign matter, such as water and oxygen, from penetrating the light-emitting element layer 5. The inorganic sealing films 26 and 28 can be formed of a silicon oxide film, a silicon nitride film, a silicon oxynitride film, or a layered film of these, formed by CVD, for example. The organic sealing film 27 can be formed of a coatable photosensitive organic material such as a polyimide or an acrylic.

The function film 39 has an optical compensation function, a touch sensor function, a protection function, or the like, for example.

The light-emitting element layer 5 includes a plurality of light-emitting elements 50. The light-emitting element 50 is a light source that illuminates each of the pixels of the display device 1. In the first embodiment, the display device 1 expresses an image using a plurality of red, green, and blue (RGB) pixels. Hereinafter, the red pixel (an R pixel) is referred to as Pr, the green pixel (a G pixel) is referred to as Pg, the blue pixel (a B pixel) is referred to as Pb, and the light-emitting elements 50 that illuminate the red pixel Pr, the green pixel Pg, and the blue pixel are referred to as a light-emitting element 50r, a light-emitting element 50g, and a light-emitting element 50b, respectively.

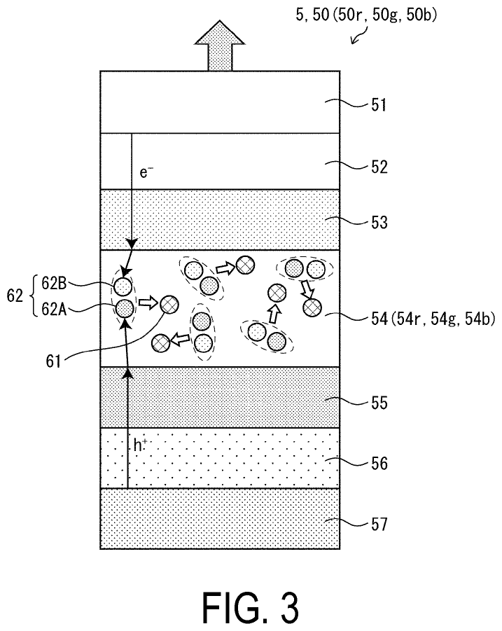

A configuration of the light-emitting element 50 will be described with reference to FIG. 3, FIG. 3 is a schematic diagram illustrating a configuration of the light-emitting element 50. Note that the light-emitting element 50r, the light-emitting element 50g, and the light-emitting element 50b, which are the light-emitting elements 50, have substantially the same configuration. Thus, in the following description, the appended letters “r”, “g”, and “b” will be omitted, and the light-emitting element 50r, the light-emitting element 50g, and the light-emitting element 50b will be collectively described as the light-emitting element 50.

As illustrated in FIG. 3, the light-emitting element 50 includes a quantum dot dopant (QD phosphor particles) 61 that emits light by receiving exciton energy from a host 62 (to be described in detail below), which is an exciplex host. Hereinafter, a direction from an anode electrode 57 to the cathode electrode 51 will be referred to as an upward direction. The direction opposite to the upward direction will be referred to as a downward direction.

The light-emitting element 50 includes the cathode electrode 51, an electron injection layer (EIL) 52, an electron transportation layer (ETL) 53, a light-emitting layer 54, a hole transportation layer (HTL) 55, a hole injection layer (HIL) 56, and the anode electrode 57, which are provided sequentially in that order from the upper side in the downward direction.

The cathode electrode 51 is an electrode that supplies electrons to the light-emitting layer 54, The cathode electrode 51 is formed of an Mg—Ag alloy, for example. The cathode electrode 51 is a transmissive electrode that transmits light emitted from the light-emitting layer 54. The light-emitting element 50 is configured as a top-emitting light-emitting element that emits the light emitted from the light-emitting layer 54 in the upward direction.

The electron injection layer 52 is a layer that promotes injection of the electrons from the cathode electrode 51 to the light-emitting layer 54. The electron injection layer 52 contains a material with excellent electron injection properties.

The electron transportation layer 53 is a layer that promotes supply of the electrons from the cathode electrode 51 to the light-emitting layer 54. The electron transportation layer 53 contains a material with excellent electron transport properties. The material having excellent electron transport properties may be the same material as that of electron transport hosts 62B, which will be described below, or may be a different material therefrom. The material having excellent electron transport properties is preferably the same material as that of the electron transport hosts 62B of the light-emitting layer 54, as light can be emitted with a low voltage. The electron transportation layer 53 can be formed by vapor deposition or coating.

The light-emitting layer 54 includes the quantum dot dopant 61, and the host 62 formed of a hole transport host 62A and the electron transport host 62B.

The quantum dot dopant 61 is a substance that receives the exciton energy from the host 62 and emits light. As an example, the material of the quantum dot dopant 61 has a core-shell structure, and may be at least one type of material selected from the group consisting of CdSe/ZnSe, CdSe/ZnS, CdS/ZnSe, CdS/ZnS, ZnSe/ZnS, InP/ZnS, and ZnO/MgO. Note that, for example, the above-described “CdSe/ZnSe” refers to a core-shell structure in which the core is formed of CdSe and the shell is formed of ZnSe.

Nano-sized crystals (semiconductor crystals) of the above-described semiconductor material are used as the material of the quantum dot dopant 61.

In FIG. 3, the quantum dot dopant 61 having a spherical shape is illustrated as an example. However, the shape of the quantum dot dopant is not limited to the spherical shape. The shape of the quantum dot dopant may be any known shape such as a rod-shape or a wire-shape.

The quantum dot dopant has high luminous efficiency and is thus suitable for improving luminous efficiency of the light-emitting element 50 (display device 1). Further, the energy band gap of the quantum dot dopant can be set by adjusting the size (the particle diameter, for example) of the quantum dot dopant. That is, by adjusting the particle diameter of the quantum dot dopant, the wavelength (more specifically, the wavelength spectrum) of the light emitted from the quantum dot dopant can be controlled. Specifically, the smaller the size of the quantum dot dopant, the shorter it is possible to make the peak wavelength (the wavelength at which the intensity peak in the wavelength spectrum can be obtained) of the light emitted from the quantum dot dopant. In the display device 1, the particle diameter is adjusted such that the quantum dot dopants included in each of the light-emitting layers 54 (a light-emitting layer 54r, a light-emitting layer 54g, and a light-emitting layer 54b) of the light-emitting element 50r, the light-emitting element 50g, and the light-emitting element Sob emit red light, green light, and blue light, respectively. Further, the spectral width of the light emitted by the quantum dot dopant is narrow, and hence the color purity of the image displayed by the display device 1 can be made high.

The host 62 is formed of the hole transport host 62A and the electron transport host 62B.

The hole transport host 62A is formed of a material having a function of transporting holes received from the hole transportation layer 55. The material that can be used to form the hole transport host 62A includes a carbazole derivative, a triazole derivative, an oxadiazole derivative, an imidazole derivative, an indorocarbazole derivative, a polyaryl alkane derivative, a pyrazoline derivative, a pyrazolone derivative, a phenylenediamine derivative, an arylamine derivative, an amino-substituted chalcone derivative, an oxazole derivative, a styryl anthracene derivative, a fluorenone derivative, a hydrazone derivative, a stilbene derivative, a silazane derivative, a porphyrin compound, an aniline copolymer, a conductive polymeric oligomer, and particularly a thiophene oligomer, for example. Among these, an aromatic tertiary amine compound and a styryl amine compound are preferably used as the material of the hole transport host 62A. More preferably, the aromatic tertiary amine compound is used as the material of the hole transport host 62A, but the material is not limited thereto. Furthermore, the material of the hole transport host 62A can be a polymeric material in which these materials are introduced into the polymer chain, or a polymeric material in which these materials are used as the main chain of the polymer, but the material is not limited thereto. The hole transport host 62A preferably has a shallow highest occupied molecular orbital (HOMO) level, so that an exciplex is easily formed between the hole transport host 62A and the above-described electron transport host 62B.

The electron transport host 62B is formed of a material having a function of transporting the electrons received from the electron transportation layer 53. The material that can be used to form the electron transport host 62B includes an oxadiazole derivative, a nitro-substituted fluorene derivative, a diphenylquinone derivative, a thiopyran dioxide derivative, a carbodiimide, a fluorenylidene methane derivative, an anthraquinone dimethane derivative, and an anthrone derivative, for example. Further, as the material of the electron transport host 62B, in the oxadiazole derivative described above, a thiadiazole derivative in which an oxygen atom of the oxadiazole ring is replaced with a sulfur atom, or a quinoxaline derivative having a quinoxaline ring known as an electron withdrawing substituent can also be used. Furthermore, the material of the electron transport host 62B can be a polymeric material in which these materials are introduced into the polymer chain, or a polymeric material in which these materials are used as the main chain of the polymer, but the material is not limited thereto. The electron transport host 62B preferably has a deep lowest unoccupied molecular orbital (LUMO) level so that the exciplex is easily formed between the hole transport host 62A and the electron transport host 62B.

The compounding ratio of the quantum dot dopants 61 and the hosts 62 in the light-emitting layer 54 is preferably set such that the quantum dot dopants 61/the hosts 62=0.5/99.5 to 50/50 in terms of the mass ratio. When an amount of the quantum dot dopants 61 is too small, the exciton energy generated in the above-described exciplex hosts is deactivated without sufficiently moving to the quantum dot dopants 61. On the other hand, when the amount of quantum dot dopants 61 is too large, movement of the electrons or the holes is inhibited, and the probability of generating the exciplex decreases.

The light-emitting layer 54 can be formed using a known method such as a spin coating method, a spray coating method, a casting method, and a printing method including an ink-jet method, for example.

Note that in FIG. 3, only the hole transport hosts 62A and the electron transport hosts 62B that are forming the exciplex hosts are illustrated. In the light-emitting layer 54 illustrated in FIG. 3, it is assumed that a region in which none of the quantum dot dopant 61, the hole transport host 62A, nor the electron transport host 62B is illustrated is filled with the hole transport hosts 62A and the electron transport host 62B that are not forming the exciplex hosts.

In the light-emitting layer 54 according to the present embodiment, the host 62 is formed by the hole transport host 62A and the electron transport host 62B. As a result, the holes and the electrons are efficiently transported to the vicinity of the quantum dot dopants.

Further, in the light-emitting element 50, the hole transport host 62A and the electron transport host 62B form the exciplex (excited complex) host. More specifically, the host 62 is the exciplex host that forms an exciton between the HOMO energy level of the hole transport host 62A and the LUMO energy level of the electron transport host 62B.

According to the configuration described above, exciton energy having the maximum internal quantum efficiency of 100% is generated in the exciplex host formed by the hole transport host 62A and the electron transport host 62B. Then, the generated exciton energy transitions to the quantum dot dopant 61 with high efficiency, thereby causing the quantum dot dopant 61 to emit light.

As described above, although the maximum internal quantum efficiency is 25% in a conventional light-emitting element in which the light-emitting layer includes fluorescence dopants, the maximum internal quantum efficiency can be made 100% in the light-emitting element 50. Thus, light emission can be achieved with high efficiency.

The hole transportation layer 55 is a layer that promotes supply of the holes from the anode electrode 57 to the light-emitting layer 54. The hole transportation layer 55 contains a material with excellent hole transport properties. The material with the excellent hole transport properties may be the same material as the hole transport host 62A of the light-emitting layer 54, or may be a different material therefrom. However, the material is preferably the same material as the hole transport host 62A of the light-emitting layer 54, as light emission can be performed at a low voltage. The hole transportation layer 55 can be formed by vapor deposition or coating.

The hole injection layer 56 is a layer that promotes injection of the holes from the anode electrode 57 to the light-emitting layer 54. The hole injection layer 56 contains a material having excellent hole injection properties.

The anode electrode 57 has a layered structure, for example, including an Ag—Pd—Cu alloy (APC) as a lower layer and indium tin oxide (ITO) as an upper layer. The anode electrode 57 is a reflective electrode that reflects the light emitted from the light-emitting layer 54. According to this arrangement, of the light emitted from the light-emitting layer 54, light traveling in the downward direction can be reflected by the anode electrode 57. As a result, usage efficiency of the light emitted from the light-emitting layer 54 can be improved. The anode electrode 57 can be formed by vapor deposition.

In the light-emitting element 50, by applying a forward voltage between the anode electrode 57 and the cathode electrode 51 (setting the anode electrode 57 to a potential higher than that of the cathode electrode 51), electrons can be supplied from the cathode electrode 51 to the light-emitting layer 54, and at the same time, holes can be supplied from the anode electrode 57 to the light-emitting layer 54. By the electrons supplied from the cathode electrode 51 and the holes supplied from the anode electrode 57, the exciton energy is generated in the exciplex hosts each formed by the hole transport host 62A and the electron transport host 62B. Then, the generated exciton energy transitions to the quantum dot dopant 61, thereby causing the quantum dot dopant 61 to emit light. The above-described application of the voltage may be controlled by the thin film transistor (TFT) Tr (see FIG. 2).

Light emission obtained by applying the voltage to the light-emitting element 50 in this manner is electro-luminescence (EL). In other words, the light-emitting element 50 functions as a self light-emitting type light-emitting element. Therefore, unlike in a liquid crystal display, a light emitting diode (LED) or the like is not needed as a backlight. Therefore, the display device 1 can be provided with a smaller size.

As described above, the light-emitting element 50 has a configuration in which the light-emitting layer 54 includes the quantum dot dopants 61, and the exciplex hosts (hosts 62) each formed of the hole transport host 62A and the electron transport host 62B, and the quantum dot dopants 61 emit light as a result of the exciton energy generated in the hosts 62 transitioning to the quantum dot dopants 61.

According to the above-described configuration, since the spectral width of the light emitted by the quantum dot dopant 61 is narrow, the color purity of the image displayed by the display device 1 can be made high.

Further, exciton energy having the maximum internal quantum efficiency of 100% is generated in the exciplex host formed of the hole transport host 62A and the electron transport host 62B. Because the quantum dot dopant 61 emits light as a result of the generated exciton energy transitioning to the quantum dot dopant 61, the light-emitting element 50 with high luminous efficiency can be realized.

Note that the light-emitting element according to an aspect of the present invention may have a configuration in which the hole injection layer 56 is not included. Further, the light-emitting element according to an aspect of the present invention may have a configuration in which the electron injection layer 52 is not included.

Further, it is preferable that the light emission spectrum of the exciplex host (the host 62) formed by the hole transport host 62A and the electron transport host 62B overlap with an absorption spectrum of the quantum dot dopant 61, and it is more preferable that the overlapping range be large. As a result, energy transfer from the host 62 to the quantum dot dopant 61 can be efficiently performed.

Further, it is preferable that an average distance between the exciplex generated in the host 62 and the quantum dot dopant 61 be close, for example, 10 nm or less. As a result, energy transfer from the above-described exciplex host to the quantum dot dopant 61 can be efficiently performed.

### Modification Example

The light-emitting element 50 may be configured as a bottom-emitting type light-emitting element. In other words, the light-emitting element 50 may be configured to emit the light emitted from the light-emitting layer 54 in the downward direction. Specifically, a bottom-emitting type light-emitting element 50 can be achieved by using a reflective electrode as the cathode electrode 51 and a light-transmissive electrode as the anode electrode 57 respectively. In the bottom-emitting type light-emitting element 50, a substrate (not illustrated) provided below the anode electrode 57 is a light-transmissive substrate (a glass substrate, for example).

### Second Embodiment

A light-emitting element 50A according to another embodiment of the present invention will be described below. For convenience of description, members having the same function as the members stated in the embodiment above are denoted by the same reference signs, and a description thereof is omitted.

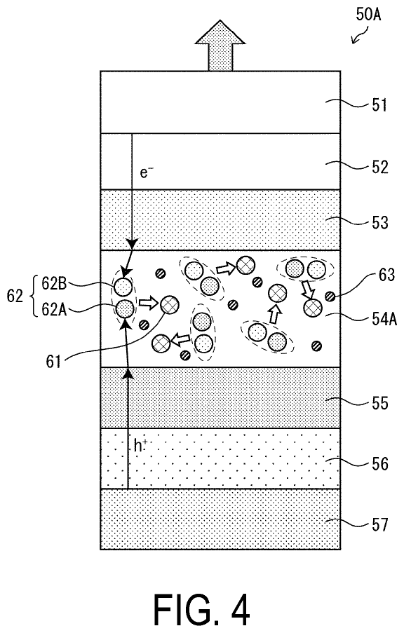

FIG. 4 is a schematic diagram illustrating a configuration of the light-emitting element 50A. As illustrated in FIG. 4, the light-emitting element 50A includes a light-emitting layer 54A in place of the light-emitting layer 54 of the light-emitting element 50 in the first embodiment.

In addition to the configuration of the light-emitting layer 54 in the first embodiment, the light-emitting layer 54 includes photosensitive hosts 63.

The photosensitive hosts 63 are used for patterning the light-emitting layer 54A by exposure and development. Examples of the material of the photosensitive host 63 include a photosensitive resin such as SU-8 (manufactured by Nippon Kayaku Co., Ltd.), the Ki series (manufactured by Hitachi Chemical Co., Ltd.), AZ photoresist (manufactured by Merck & Co., Inc.), or Sumiresist (manufactured by Sumitomo Chemical Co., Ltd.), Further, the photosensitive host 63 may contain a photopolymerization initiator.

Since the light-emitting element 50A includes the hosts 62 formed by the hole transport host 62A and the electron transport host 62B, the light-emitting device 50A can improve the luminous efficiency, even when the light-emitting layer 54A is manufactured using the photosensitive hosts 63 having poor carrier transport properties.

### Supplement

A light-emitting element (50, 50A) according to a first aspect of the resent invention includes a light-emitting layer (54, 54A) provided between an anode electrode (57) and a cathode electrode (51), a hole transportation layer (55) provided between the anode electrode and the cathode electrode and configured to transport holes supplied from the anode electrode to the light-emitting layer, and an electron transportation layer (53) provided between the anode electrode and the cathode electrode and configured to transport electrons supplied from the cathode electrode to the light-emitting layer. The light-emitting layer includes a quantum dot dopant (61), and an exciplex host (the host 62) formed of a hole transport host (62A) and an electron transport host (62B), and the quantum dot dopant emits light as a result of exciton energy generated in the exciplex host transitioning to the quantum dot dopant.

According to the above-described configuration, since the spectral width of light emitted by the quantum dot dopant is narrow, the color purity of an image displayed by a display device can be made high.

Further, the exciton energy having the maximum internal quantum efficiency of 100% is generated in the exciplex host formed by the hole transport host and the electron transport host. Then, since the quantum dot dopant emits light as a result of the generated exciton energy transitioning to the quantum dot dopant, the light-emitting element with high luminous efficiency can be realized.

In the light-emitting element according to a second aspect of the present invention, in the first aspect, the light-emitting layer further includes a photosensitive host (63).

In the light-emitting element according to a third aspect of the present invention, in the first or second aspect, a material forming the hole transportation layer is the same as a material of the hole transport host.

According to the above-described configuration, light can be emitted at a low voltage.

In the light-emitting element according to a fourth aspect of the present invention, in the first or second aspect, a material forming the electron transportation layer is the same as a material of the electron transport host.

In the light-emitting element according to a fifth aspect of the present invention, in the first or second aspect, a material forming the hole transportation layer is the same as a material of the hole transport host, and a material forming the electron transportation layer is the same as a material of the electron transport host.

In the light-emitting element according to a sixth aspect of the present invention, in the first or second aspect, the quantum dot dopant has a core-shell structure and is formed of at least one type of material selected from the group consisting of CdSe/ZnSe, CdSe/ZnS, CdS/ZnSe, CdS/ZnS, ZnSe/ZnS, InP/ZnS, and ZnO/MgO.

In the light-emitting element according to a seventh aspect of the present invention, in any one of the first to sixth aspects, a light emission spectrum of the exciplex host overlaps with an absorption spectrum of the quantum dot dopant.

In the light-emitting element according to an eight aspect of the present invention, in any one of the first to seventh aspects, an average distance between an exciplex generated in the exciplex host and the quantum dot dopant is not more than 10 nm.

In any one of the first to eight aspects, the light-emitting element according to a ninth aspect of the present invention includes a hole injection layer configured to inject the holes supplied from the anode electrode into the hole transportation layer.

In any one of the first to ninth aspects, the light-emitting element according to a tenth aspect of the present invention includes an electron injection layer configured to inject the electrons supplied from the cathode electrode into the electron transportation layer.

A display device (1) according to an eleventh aspect of the present invention includes a plurality of the light-emitting element of one of the first to tenth aspects.

### Additional Items

The present invention is not limited to the embodiments described above, and various modifications may be made within the scope of the claims. Embodiments obtained by appropriately combining technical approaches disclosed in each of the different embodiments also fall within the technical scope of the present invention. Moreover, novel technical features can be formed by combining the technical approaches disclosed in each of the embodiments.

### REFERENCE SIGNS LIST

1 Display device
50, 50A Light-emitting element
51 Cathode electrode
52 Electron injection layer
53 Electron transportation layer
54, 54A Light-emitting layer
55 Hole transportation layer
56 Hole injection layer
57 Anode electrode
61 Quantum dot dopant
62 Host (exciplex host)
62A Hole transport host
62B Electron transport host
63 Photosensitive host

1. A light-emitting element comprising:
a light-emitting layer provided between an anode electrode and a cathode electrode;
a hole transportation layer provided between the anode electrode and the cathode electrode and configured to transport holes supplied from the anode electrode to the light-emitting layer; and
an electron transportation layer provided between the anode electrode and the cathode electrode and configured to transport electrons supplied from the cathode electrode to the light-emitting layer,
wherein the light-emitting layer includes a quantum dot dopant, and an exciplex host formed of a hole transport host and an electron transport host, and
the quantum dot dopant emits light as a result of exciton energy generated in the exciplex host transitioning to the quantum dot dopant.

2. The light-emitting element according to claim 1,
wherein the light-emitting layer further includes a photosensitive host.

3. The light-emitting element according to claim 1,
wherein a material forming the hole transportation layer is the same as a material of the hole transport host.

4. The light-emitting element according to claim 1,
wherein a material forming the electron transportation layer is the same as a material of the electron transport host.

5. The light-emitting element according to claim 1,
wherein a material forming the hole transportation layer is the same as a material of the hole transport host, and
a material forming the electron transportation layer is the same as a material of the electron transport host.

6. The light-emitting element according to claim 1,
wherein the quantum dot dopant has a core-shell structure and is formed of at least one type of material selected from the group consisting of CdSe/ZnSe, CdSe/ZnS, CdS/ZnSe, CdS/ZnS, ZnSe/ZnS, InP/ZnS, and ZnO/MgO.

7. The light-emitting element according to claim 1,
wherein a light emission spectrum of the exciplex host overlaps with an absorption spectrum of the quantum dot dopant.

8. The light-emitting element according to claim 1,
wherein an average distance between an exciplex generated in the exciplex host and the quantum dot dopant is not more than 10 nm.

9. The light-emitting element according to claim 1, further comprising:
a hole injection layer configured to inject the holes supplied from the anode electrode into the hole transportation layer.

10. The light-emitting element according to claim 1, further comprising:
an electron injection layer configured to inject the electrons supplied from the cathode electrode into the electron transportation layer.

11. A display device comprising:
a plurality of the light-emitting elements of claim 1.
